(19) United States
(12) Patent Application Publication
(10) Pub. No.: US 2026/0255735 A1
(43) Pub. Date: Aug. 27, 2026

(54) LIGHT-EMITTING DEVICE AND MANUFACTURING METHOD THEREOF

(71) Applicant: ENNOSTAR CORPORATION, Hsinchu City (TW)

(72) Inventors: Yen-Liang KUO, Hsinchu City (TW); Bo-Ting Wu, Hsinchu City (TW); KUANG-YANG KUO, Kaohsiung City (TW); CHUN HAN LU, Hsinchu City (TW)

(21) Appl. No.: 19/546,912

(22) Filed: Feb. 23, 2026

(30) Foreign Application Priority Data
Feb. 25, 2025 (TW) 114106806

(51) Int. Cl. H10H 20/816; H10H 20/841

(52) U.S. Cl. CPC H10H 20/8162; H10H 20/841

(57) ABSTRACT

A semiconductor device, includes: a semiconductor stack including an upper surface and a side surface; a first current blocking structure disposed on the upper surface, and includes: a bottom structure including a first portion and a second portion; and a reflective structure disposed on the first portion without covering the second portion; a protective structure located on the side surface and spaced apart from the first current blocking structure; and a conductive layer covering the first current blocking structure; wherein the protective structure and the bottom structure include the same material, and the protective structure and the second portion have substantially the same thickness.

### CROSS-REFERENCE TO RELATED APPLICATIONS

This application claims priority to and the benefit of Taiwan patent application No. 114106806 filed on Feb. 25, 2025, and the content of which is incorporated by reference in its entirety.

### BACKGROUND

### Technical Field

The present application relates to a semiconductor device, and in particular to a semiconductor device having a current blocking structure.

### Description of the Related Art

Semiconductor devices such as light-emitting diodes (LEDs) feature low power consumption, low heat generation, long operating life, impact resistance, small size, and fast response, and are thus widely used in fields that require light-emitting devices, such as vehicles, home appliances, 3C products, displays, and lighting fixtures.

A conventional LED includes a substrate, an n-type semiconductor structure, an active structure, and a p-type semiconductor structure formed on the substrate, as well as p and n electrodes formed on the p-type and n-type structures, respectively. When a forward bias above a specific threshold is applied through the electrodes, holes from the p-type structure and electrons from the n-type structure recombine in the active structure to emit light. While the LEDs are incorporated into various optoelectronic products whose volumes are getting smaller, a smaller size of the LED with qualified photoelectric characteristics and manufacturing yield is also desired.

### SUMMARY OF THE DISCLOSURE

A semiconductor device, includes: a semiconductor stack including an upper surface and a side surface; a first current blocking structure disposed on the upper surface, and includes: a bottom structure including a first portion and a second portion; and a reflective structure disposed on the first portion without covering the second portion; a protective structure located on the side surface and spaced apart from the first current blocking structure; and a conductive layer covering the first current blocking structure; wherein the protective structure and the bottom structure include the same material, and the protective structure and the second portion have substantially the same thickness.

### BRIEF DESCRIPTION OF THE DRAWINGS

FIG. 1 shows a plan view schematic of a semiconductor device in accordance with an embodiment of the present application.

FIG. 2A shows a cross-sectional view of the semiconductor device taken along an A-A′ line in FIG. 1.

FIG. 2B shows a cross-sectional view of the semiconductor device taken along a B-B′ line in FIG. 1.

FIGS. 3A and 3B show partial enlarged views of a region of FIG. 2A in accordance with some embodiments of the present application.

FIG. 4 shows details of a reflective structure of a first current blocking structure in accordance with an embodiment of the present application.

FIG. 5 shows a plan view schematic of a semiconductor device in accordance with another embodiment of the present application.

FIGS. 6A and 6B show cross-sectional views of the semiconductor device taken along a B-B′ line in FIG. 5.

FIGS. 7A-7D show cross-sectional views of the semiconductor device in different manufacturing stages in accordance with an embodiment of the present application.

### DETAILED DESCRIPTION

Numerous embodiments or examples are provided herein to implement different elements of the subject matter. Specific examples of components and configurations are described below to simplify the description of the embodiments. These examples are not intended to limit the scope of the embodiments. Unless otherwise specified, elements with the same reference numerals are assumed to be identical or similar elements with the same material composition and the same function.

In the present application, unless otherwise specified, the general formula InGaP represents Inₓ₀Ga₁₋ₓ0P, where 0<x0<1; AlInP represents Alₓ₁In₁₋ₓ₁P, where 0<x1<1; AlGaInP represents Alₓ₂Gaₓ₃In₁₋ₓ₂₋ₓ₃P, where 0<x2<1 and 0<x3<1; InGaAsP represents Inₓ₄Ga₁₋ₓ₄Asₓ₅P₁₋ₓ₅, where 0<x4<1 and 0<x5<1; AlGaInAs represents Alₓ₆Gaₓ₇In₁₋ₓ₆₋ₓ₇As, where 0<x6<1 and 0<x7<1; InGaNAs represents Inₓ₈Ga₁₋ₓ₈Nₓ₉As₁₋ₓ₉, where 0<x8<1 and 0<x9<1; InGaAs represents Inₓ₁₀Ga₁₋ₓ₁₀As, where 0<x10<1; AlGaAs represents Alₓ₁₁Ga₁₋ₓ₁₁As, where 0<x11<1; AlInGaN represents Alₓ₁₂Inₓ₁₃Ga₁₋ₓ₁₂₋ₓ₁₃N, where 0<x12<1 and 0<x13<1; Inₓ₁₄Ga₁₋ₓ₁₄Asₓ₁₅N₁₋ₓ₁₅, where 0<x14<1 and 0<x15<1; and AlGaAsP represents Alₓ₁₆Ga₁₋ₓ₁₆Asₓ₁₇P₁₋ₓ₁₇, where 0<x16<1 and 0<x17<1.

The content of each element may be adjusted for different purposes, including but not limited to adjusting the band gap.

The semiconductor device disclosed may include light-emitting elements (e.g., a light-emitting diode (LED) or a laser diode), light-absorbing elements (e.g., a photodetector), or other non-light-emitting elements. The composition and dopants of each layer may be analyzed by any suitable method, such as secondary ion mass spectrometry (SIMS), and the thickness of each layer may be analyzed by any suitable method, such as transmission electron microscopy (TEM) or scanning electron microscopy (SEM).

The present application provides a semiconductor device having a current blocking structure and a protective structure. The current blocking structure blocks current from directly injecting into the semiconductor stack right beneath an electrode, thereby increasing current spreading. The protective structure protects the semiconductor stack to increase device reliability.

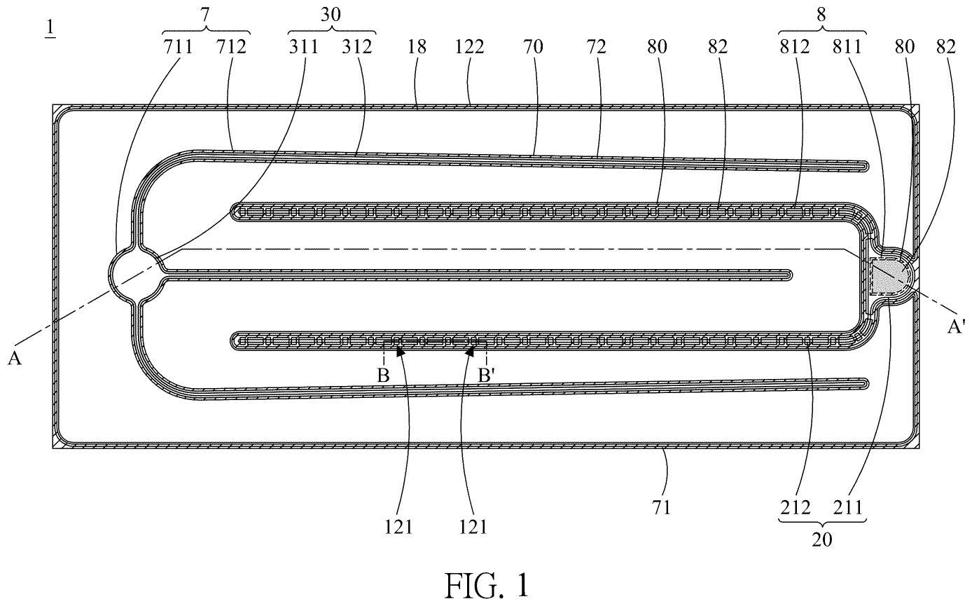

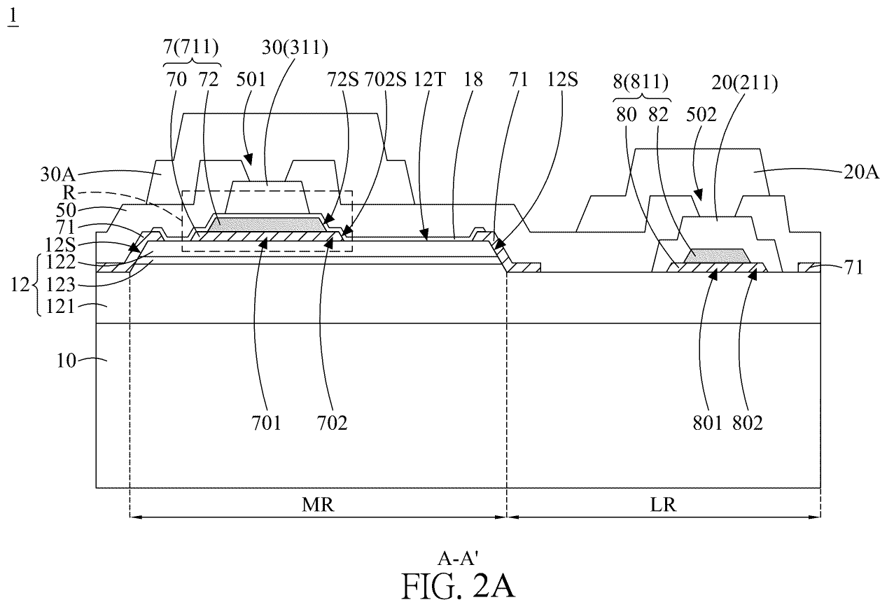

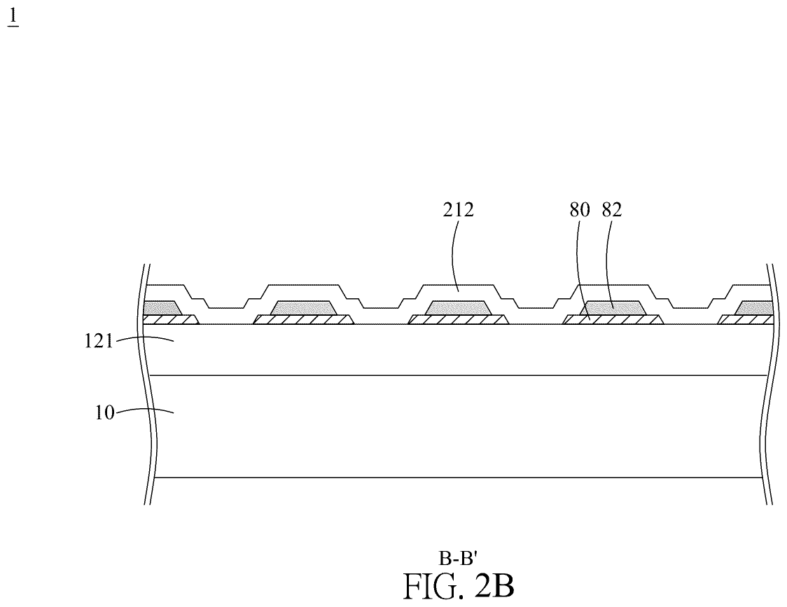

Referring to FIGS. 1, 2A, and 2B, FIG. 1 is a plan view of a semiconductor device 1 in accordance with an embodiment of the present application, wherein some components are omitted in FIG. 1. FIG. 2A is a cross-sectional view taken along a line A-A′ in FIG. 1. FIG. 2B is a cross-sectional view taken along a line B-B′ in FIG. 1. In an embodiment, the semiconductor device 1 includes a semiconductor stack 12, a first current blocking structure 7 on an upper surface 12T of the semiconductor stack 12, a protective structure 71 on a side surface 12S of the semiconductor stack 12, and a conductive layer 18 covering the first current blocking structure 7.

As shown in FIGS. 1, 2A and 2B, the semiconductor stack 12 includes a first-type semiconductor structure 121, an active structure 123 on the first-type semiconductor structure 121, and a second-type semiconductor structure 122 on the active structure 123. The active structure 123 is between the first-type semiconductor structure 121 and the second-type semiconductor structure 122.

The first-type semiconductor structure 121 has a first conductivity type, and the second-type semiconductor structure 122 has a second conductivity type different from the first. For example, the first conductivity type may be n-type and the second conductivity type may be p-type, or the first conductivity type may be p-type and the second conductivity type may be n-type. Thus, the first-type semiconductor structure 121 and the second-type semiconductor structure 122 respectively provide electrons and holes, or holes and electrons. In some embodiments, the conductivity types can be adjusted by dopants, which include Group II, Group IV, or Group VI elements, such as carbon (C), zinc (Zn), silicon (Si), germanium (Ge), tin (Sn), selenium (Se), magnesium (Mg), or tellurium (Te).

The first-type semiconductor structure 121, active structure 123, and second-type semiconductor structure 122 each includes III-V semiconductor materials, such as aluminum (Al), gallium (Ga), arsenic (As), phosphorus (P), nitrogen (N), or indium (In). In some embodiments, the III-V materials may be binary compound semiconductors (e.g., GaAs, GaP, or GaN), ternary compound semiconductors (e.g., InGaAs, AlGaAs, InGaP, AlInP, InGaN, or AlGaN), or quaternary compound semiconductors (e.g., AlGaInAs, AlGaInP, AlInGaN, InGaAsP, InGaNAs, or AlGaAsP).

In some embodiments, the semiconductor stack 12 may include a single heterostructure (SH), double heterostructure (DH), double-side double heterostructure (DDH), or multiple quantum wells (MQW). In some embodiments, the semiconductor device 1 can be a light-emitting device and the active structure 123 emits light during operation. The light can be visible or invisible. The wavelength of the light depends on the composition of the semiconductor stack 12. For example, when the semiconductor stack 12 includes AlGaN, the semiconductor stack 12 emits ultraviolet light with peak wavelength of 250-400 nm. When the semiconductor stack 12 includes InGaN, the semiconductor stack 12 emits deep blue or blue light with peak wavelength of 400-490 nm, green or yellow light with peak wavelength of 490-550 nm, or red light with peak wavelength of 560-650 nm. When the semiconductor stack 12 includes InGaP or AlGaInP, the semiconductor stack 12 emits yellow, orange or red light with peak wavelength of 530-700 nm. When the semiconductor stack 12 includes InGaAs, InGaAsP, AlGaAs, or AlGaInAs, the semiconductor stack 12 emits infrared light with peak wavelength of 700 -1700 nm.

In some embodiments, the semiconductor stack 12 includes a platform region LR and a mesa region MR. The mesa region MR protrudes above the platform region LR, i.e., the mesa region MR has greater thickness than the platform region LR. The mesa region MR includes the upper surface 12T and side surface 12S. The mesa region MR includes portions of the first-type semiconductor structure 121, active structure 123, and the second-type semiconductor structure 122, while the platform region LR includes another portion of the first-type semiconductor structure 121.

In some embodiments, the semiconductor device 1 optionally includes a substrate 10 on which the semiconductor stack 12 is disposed. The substrate 10 may be a growth substrate or a transferred substrate. The substrate 10 may be insulating or non-insulating. Insulating materials include sapphire, glass, or ceramic. Non-insulating materials include elemental semiconductors (e.g., silicon or germanium), compound semiconductors (e.g., silicon carbide, gallium arsenide, gallium nitride, aluminum nitride, aluminum gallium nitride, or combinations thereof), metals (e.g., copper, molybdenum, or copper tungsten), or combinations thereof. The substrate 10 may be multilayered, such as a silicon-on-insulator (SOI) substrate. In an embodiment where substrate 10 serves as a growth substrate, the epitaxial structure (e.g., the first-type semiconductor structure 121, active structure 123, and second-type semiconductor structure 122) may be grown on substrate 10 using, for example, metal-organic chemical vapor deposition (MOCVD).

Referring to FIGS. 1, 2A and 2B, the semiconductor device 1 further includes the first current blocking structure 7, a first electrode 30, and a second electrode 20. The semiconductor device 1 may optionally include a conductive layer 18. The conductive layer 18 covers the first current blocking structure 7 and extends on the upper surface 12T of the semiconductor stack 12. The second electrode 20 is electrically connected to the first-type semiconductor structure 121. The first electrode 30 is electrically connected to the conductive layer 18 and the second-type semiconductor structure 122. The first current blocking structure 7 is located on the second-type semiconductor structure 122, i.e., on the mesa region MR. The structure 7 blocks current from the first electrode 30 from directly injecting into the semiconductor stack 12 right beneath the first electrode 30, and, together with the conductive layer 18, increases lateral current spreading. As shown in FIG. 2A, the first current blocking structure 7 includes a bottom structure 70 and a reflective structure 72 disposed (e.g., stacked) on a first portion 701 of the bottom structure 70. In some embodiments, the reflective structure 72 has a higher reflectivity at the emission wavelength of the semiconductor stack 12 than the bottom structure 70. For example, the bottom structure 70 may have a reflectivity of about 5% to 50% at the emission wavelength, whereas the reflective structure 72 may have a reflectivity of about 70% to 100%. Thus, light emitted by the semiconductor stack 12 and traveling toward the first electrode 30 can be reflected by the bottom structure 70 and/or the reflective structure 72 beneath the first electrode 30 and be extracted from other portions of the semiconductor device 1, thereby enhancing brightness.

In some embodiments, as shown in FIG. 2A, the first electrode 30 is on the conductive layer 18 and overlaps the first current blocking structure 7. In other words, the first current blocking structure 7 is between the semiconductor stack 12 and the first electrode 30. The first electrode 30 is electrically connected to the second-type semiconductor structure 122 through the conductive layer 18. In some embodiments, in plan view, the area of the first current blocking structure 7 is larger than that of the overlying first electrode 30, providing sufficient reflective area to increase brightness. In some embodiments, the area of the bottom structure 70 is larger than that of the reflective structure 72. In plan view, each of the bottom structure 70, the reflective structure 72, and the first electrode 30 has a projection onto the upper surface 12T. The contour of the projection of the reflective structure 72 lies between the contours of the respective projections of the first electrode 30 and the bottom structure 70. In cross-sectional view, the side surface of the first current blocking structure 7 may have a stepped profile, thereby enhancing the step coverage of the conductive layer 18 over the structure.

As shown in FIG. 1, the first electrode 30 includes a first contact portion 311 and optionally one or more first extending portions 312 extending from the first contact portion 311. The first current blocking structure 7 may be disposed corresponding to the first electrode 30. In some embodiments, the first electrode 30 and the first current blocking structure 7 have the same shape in the plan view. The overall shape of the first current blocking structure 7 can be regarded as the shape of the bottom structure 70, that is, the first electrode 30 and bottom structure 70 have the same top-view shape. In other embodiments, the first electrode 30 and bottom structure 70 have different top-view shapes. The bottom structure 70 and reflective structure 72 may have the same or different top-view shapes; likewise, the first electrode 30 and reflective structure 72 may have the same or different top-view shapes.

The first current blocking structure 7 includes a first pad portion 711 corresponding to the first contact portion 311, and optionally one or more first finger portions 712 corresponding to the one or more first extending portions 312. FIG. 1 shows three first finger portions 712 corresponding to three first extending portions 312, but the number and shapes of the first finger portions 712 may be designed as needed. For example, the first current blocking structure 7 may include only the first pad portion 711 without first finger portions 712, or the first finger portion 712 may include multiple separated sections disposed along the first extending portion 312. In other embodiments (not shown), the first pad portion 711 may include an opening, and the conductive layer 18 above it may include a corresponding opening. The first contact portion 311 may be filled into these openings to connect to the second-type semiconductor structure 122. Although the cross-sectional view of the A-A′ line does not show the first finger portions 712 and the first extending portions 312, one skilled in the art could understand that each first finger portion 712 may include the bottom structure 70 and the reflective structure 72 like the first pad portion 711. Depending on various electrode designs and objectives for light extraction and current spreading, in different embodiments the first pad portion 711, the finger portion 712, or both may include the bottom structure 70, the reflective structure 72, or both.

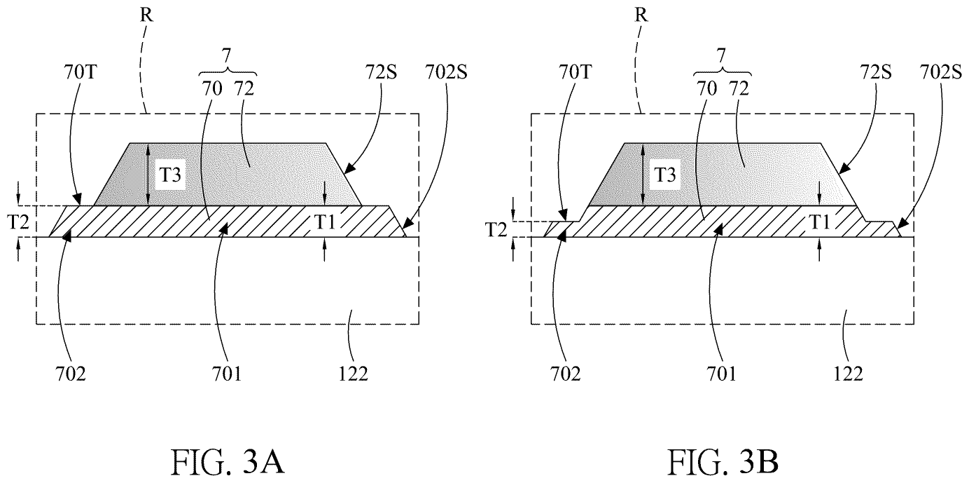

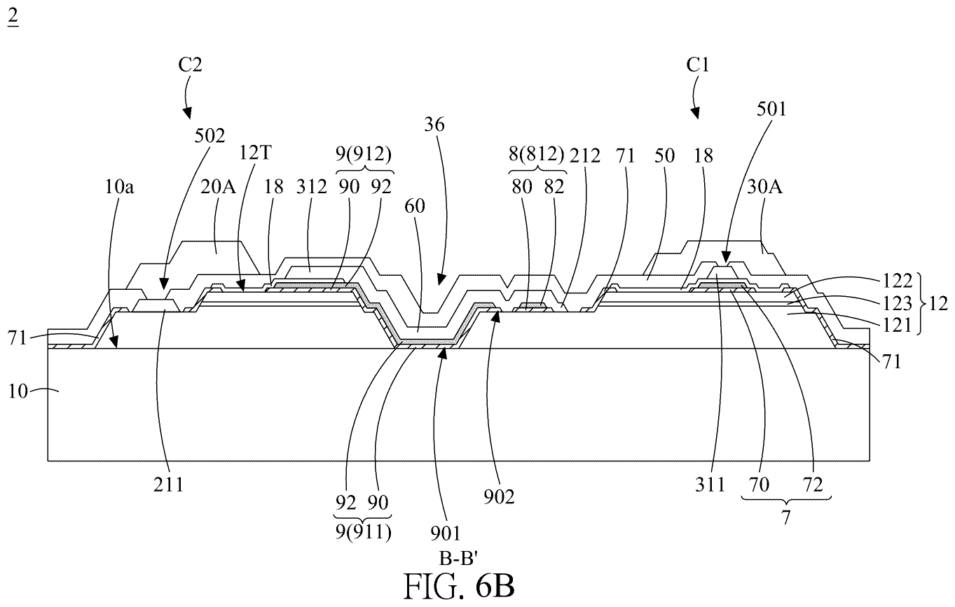

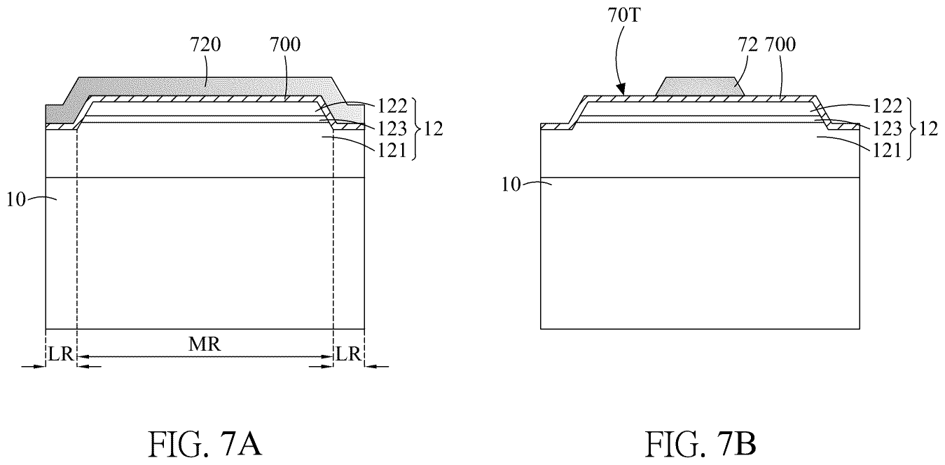

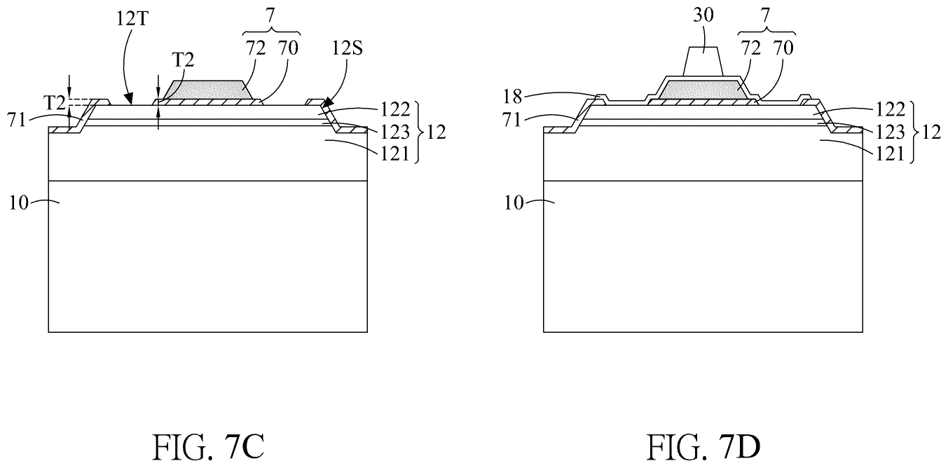

Detailed cross-section of the first current blocking structure 7 is shown in FIGS. 3A and 3B, which are partial enlarged views of region R in FIG. 2A. In some embodiments, the bottom structure 70 includes a first portion 701 and a second portion 702 connected with each other. The reflective structure 72 covers the first portion 701 but does not cover the second portion 702. In the plan view, the reflective structure 72 is surrounded by the second portion 702. In one embodiment shown on FIG. 3A, the first portion 701 has a thickness T1 and the second portion 702 has a thickness T2, where T1 is substantially equal to T2. In another embodiment shown in FIG. 3B, T1 is greater than T2. The side surface of the bottom structure 70 forms a step. The thickness T2 of the second portion 702 depends on the etching process conditions used to pattern the first current blocking structure 7, described later with reference to FIGS. 7B and 7C.

In some embodiments, the thickness of the bottom structure 70 (e.g., thickness T1 of the first portion 701) is less than the thickness T3 of the reflective structure 72, thereby reducing light absorption by the bottom structure 70 and improving light extraction. In some embodiments, the reflective structure 72 includes a first side surface 72S, and the second portion 702 includes a second side surface 702S, where the slope of 702S is gentler than that of 72S. Accordingly, the conductive layer 18 and an insulating structure 50 disposed on the first current blocking structure 7 exhibit improved conformality as they extend to cover the second-type semiconductor structure 122, thereby reducing the risk of cracking. In other embodiments, as shown in FIG. 3B, the second side surface 702S of the second portion 702 includes an upper segment located above a plane 70T and a lower segment located below the plane 70T, where the lower segment has a slope gentler than that of the upper segment. The upper segment may have a slope substantially equal to that of the first side surface 72S. In different embodiments, the first side surface 72S and/or the second side surface 702S may include curved portions.

In some embodiments, the bottom structure 70 may be a single-layer or multilayered stack. The bottom structure 70 may include insulating materials such as silicon oxide, silicon nitride, silicon oxynitride, niobium oxide, hafnium oxide, titanium oxide, magnesium fluoride, aluminum oxide, or combinations thereof. In some embodiments, the bottom structure 70 may include a dense layer (not shown) formed by atomic layer deposition (ALD) over the surface of the semiconductor stack 12 to conformally cover the stack 12. Due to good step coverage, the dense layer provides better protection for the semiconductor stack 12 such as preventing an ingress of moisture into the semiconductor device 1.

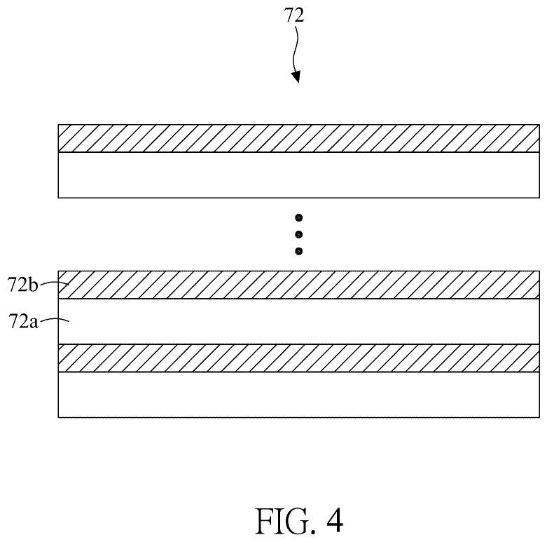

In some embodiments, the reflective structure 72 includes a distributed Bragg reflector. Details are shown in FIG. 4. The reflective structure 72 may include one or more pairs of stacked layers having different refractive indices and provides reflection for a specific wavelength range and/or incident angle range. In some embodiments, the reflective structure 72 includes one or more pairs of first sublayers 72a and second sublayers 72b, where the first sublayer 72a has a higher refractive index than the second sublayer 72b. The reflective structure 72 is configured by selecting materials with different refractive indices and designing the layer thicknesses to provide high reflectivity over a target wavelength range. In some embodiments, the first sublayer 72a has a smaller thickness than the second sublayer 72b. The sublayers may include insulating materials such as silicon oxide, silicon nitride, silicon oxynitride, niobium oxide, hafnium oxide, titanium oxide, magnesium fluoride, aluminum oxide, etc.

Returning to FIGS. 1, 2A and 2B, the semiconductor device 1 may optionally include a second current blocking structure 8 located between the first-type semiconductor structure 121 and the second electrode 20. The second current blocking structure 8 is disposed on the platform region LR. The second current blocking structure 8 blocks current from the second electrode 20 from directly injecting into the semiconductor stack 12 beneath the second electrode 20, increasing lateral current spreading. The second electrode 20 includes a second contact portion 211 and optionally a second extending portion 212 extending from the second contact portion 211. As shown in FIG. 1, in the plan view, the second current blocking structure 8 includes a second pad portion 811 corresponding to the second contact portion 211 and, optionally, second finger portions 812 corresponding to the second extending portion 212. In one embodiment, as shown in FIGS. 1 and 2B, the second finger portion 812 may include multiple separated sections, and the second extending portion 212 contacts the first-type semiconductor structure 121 between these sections.

In different embodiments, the area of the second pad portion 811 may be greater or smaller than that of the second contact portion 211. As shown in FIGS. 1 and 2A, when the area of the second pad portion 811 is smaller than that of the second contact portion 211, the second contact portion 211 covers the second pad portion 811 and contact the first-type semiconductor structure 121. When the area of the second pad portion 811 is larger than that of the second contact portion 211, the second contact portion 211 is above the second pad portion 811 and does not contact the first-type semiconductor structure 121 directly.

As shown in FIGS. 2A and 2B, the second current blocking structure 8 includes a bottom structure 80 and a reflective structure 82 disposed (e.g., stacked) on the bottom structure 80. The bottom structure 80 includes a third portion 801 and a fourth portion 802. The reflective structure 82 overlaps the third portion 801 and does not cover the fourth portion 802. In one embodiment, the first and second current blocking structures 7 and 8 may include the same materials and stacks; for example, bottom structures 70 and 80 include the same materials/stacks, and reflective structures 72 and 82 include the same materials/stacks. For brevity, the detailed description of the second current blocking structure 8 is omitted because it is similar to the first current blocking structure 7; reference is made to the foregoing description of the first current blocking structure 7.

As shown in FIG. 2A, the semiconductor device 1 may optionally include a protective structure 71 located on the side surface 12S of the semiconductor stack 12 and spaced apart from the first current blocking structure 7. The protective structure 71 extends from the upper surface 12T to the side surface 12S and further to the upper surface of the platform region LR. The protective structure 71 protects the semiconductor device 1 or the semiconductor stack 12, for example, by blocking moisture ingress. In some embodiments, the protective structure 71 and the bottom structure 70 are formed by the same deposition process and patterning, and thus may include the same material. In some embodiments, during the patterning process, the protective structure 71 and the second portion 702 of the bottom structure 70 are subjected to the same etching process and thus have substantially the same thickness (e.g., thickness T2 shown in FIG. 3A or 3B). In some embodiments, the protective structure 71 and the bottom structure 80 may include the same material, and the protective structure 71 and the fourth portion 802 may have substantially the same thickness. In some embodiments, the second portion 702 and the fourth portion 802 may include the same material. The second portion 702 and the fourth portion 802 may have substantially the same thickness. Methods of forming the first current blocking structure 70 and the protective structure 71 are described later. In some embodiments, the protective structure 71 and the bottom structure 80 may be separated or connected with each other as shown FIG. 1.

As shown in FIG. 2A, in some embodiments, the conductive layer 18 further extends to cover the protective structure 71. Accordingly, during patterning of the conductive layer 18, etchants can be prevented from contacting the underlying semiconductor stack 12, thereby reducing the risk of damage. In other embodiments, the conductive layer 18 does not overlap the protective structure 71. The conductive layer 18 is used to spread current and to form good electrical contact (e.g., ohmic contact) with the second-type semiconductor structure 122. In an embodiment, the conductive layer 18 is transparent to light emitted by the active structure 123. For example, the transmittance is greater than 80%. The conductive layer 18 may be formed of a metal or a transparent conductive material. Examples of metals include Au and Ni/Au. Examples of transparent conductive materials include graphene, indium tin oxide (ITO), aluminum-doped zinc oxide (AZO), gallium-doped zinc oxide (GZO), zinc oxide (ZnO), and indium-doped zinc oxide (IZO).

The first electrode 30 and the second electrode 20 may each be single-layer or multilayer structures, and may include metals such as chromium (Cr), nickel (Ni), titanium (Ti), platinum (Pt), palladium (Pd), rhodium (Rh), silver (Ag), gold (Au), aluminum (Al), tin (Sn), copper (Cu), stacks or alloys thereof.

In some embodiments, the semiconductor device 1 optionally includes the insulating structure 50, a first bonding pad 30A, and a second bonding pad 20A. As shown in FIG. 2A, the insulating structure 50 covers the first electrode 30, conductive layer 18, protective structure 71, and second electrode 20, and has a first opening 501 and a second opening 502 located over the first electrode 30 and second electrode 20, respectively. More specifically, the openings 501 and 502 expose the first contact portion 311 and the second contact portion 211, respectively. The insulating structure 50 may be a single-layer or multilayer structure and may include insulating materials such as silicon oxide, silicon nitride, silicon oxynitride, niobium oxide, hafnium oxide, titanium oxide, magnesium fluoride, aluminum oxide, or a combination thereof. In one embodiment, like the reflective structure 72, the insulating structure 50 includes one or more pairs of stacked layers having different refractive indices stacked together, and may provide reflection for a specific wavelength or an incident angle range. Thus, the insulating structure 50 may serve as a reflective structure. For example, the insulating structure 50 may have a reflectivity of greater than 60% at the peak emission wavelength of the semiconductor stack 12. In an embodiment, the insulating structure 50 includes a distributed Bragg reflector.

The first bonding pad 30A is formed on the insulating structure 50 and fills the first opening 501 to electrically connect to the first electrode 30, and the second bonding pad 20A is formed on the insulating structure 50 and fills the second opening 502 to electrically connect to the second electrode 20. The bonding pads 30A and 20A may serve as electrical paths for delivering current from an external power source to the second-type semiconductor structure 122 and the first-type semiconductor structure 121, respectively. For example, the semiconductor device 1 may be flip-chip bonded onto a circuit carrier (not shown) by bonding the bonding pads 30A and 20A to corresponding pads on the carrier, thereby electrically connecting the semiconductor device 1 to the carrier. The semiconductor device 1 may emit light through a surface opposite to the bonding pads 20A and 30A.

In some embodiments, the bonding pads 30A and 20A include metals such as Cr, Ti, W, Au, Al, In, Sn, Ni, Pt, Ag, stacks or alloys thereof. Examples include Al/Pt, Ti/Au, Ti/Pt/Au, Cr/Au, Cr/Pt/Au, Ni/Au, Ni/Pt/Au, Cr/Al/Ti/Pt, Ti/Al/Ti/Pt/Ni/Pt, Cr/Al/Ti/Al/Ni/Pt/Au, Cr/Al/Cr/Ni/Au, or Ag/NiTi/TiW/Pt.

In other embodiments, the semiconductor device 1 may omit the insulating structure 50 and the bonding pads 20A and 30A. In such configurations, the first contact portion 311 and the second contact portion 211 serve as wire-bonding pads, and the semiconductor device 1 may emit light through the surface on which the electrodes are formed.

The first current blocking structure 7 blocks direct injection of current into the semiconductor stack 12 beneath the first electrode 30, thereby increasing lateral current spreading. The reflective structure 72 further enhances light extraction efficiency. Additionally, during the patterning process for forming the first current blocking structure 7, the bottom structure 70 protects the underlying semiconductor stack 12 from damage. Moreover, the protective structure 71 on the side surface 12S protects the semiconductor device 1 and/or the semiconductor stack 12 by blocking moisture ingress. Forming the bottom structure 70 and the protective structure 71 in the same process step reduces process complexity and manufacturing cost.

Various modifications and variations of the embodiments are described below. The same or similar reference numerals are used to indicate the same or similar elements throughout the drawings and the description.

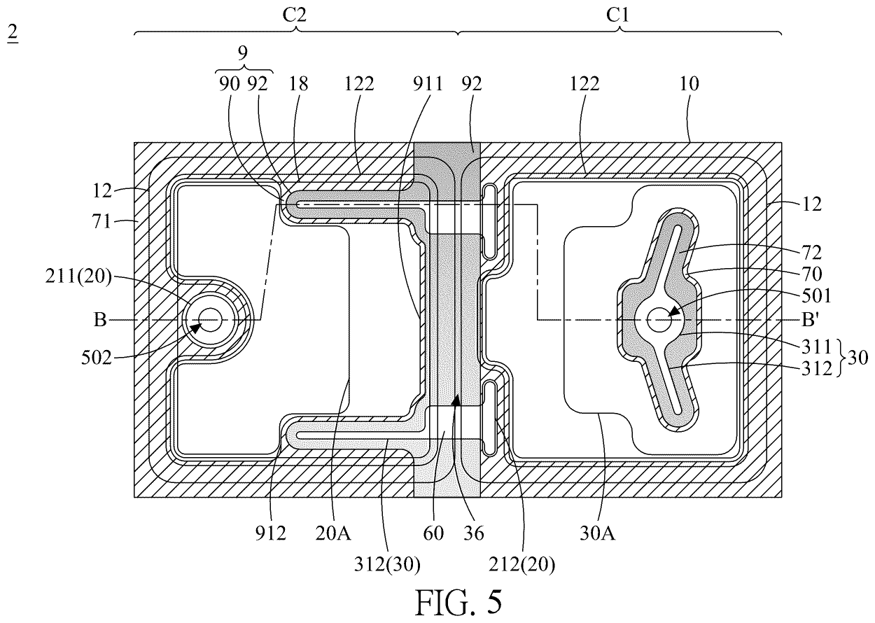

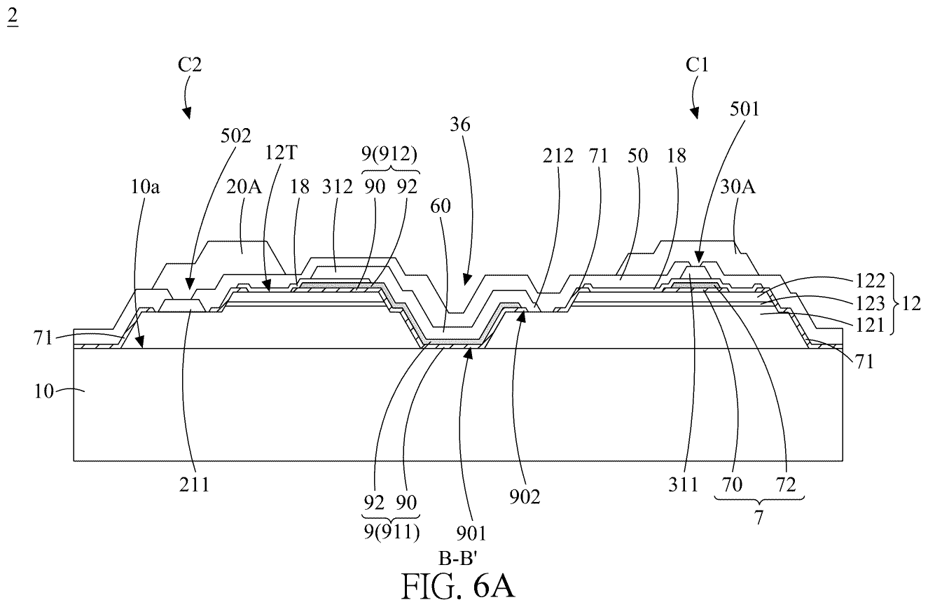

FIG. 5 shows a plan view of a semiconductor device 2 in accordance with to another embodiment of the present application. FIG. 6A shows a cross-sectional view taken along line B-B′ in FIG. 5. FIG. 6B shows a variation. The difference between the semiconductor device 2 in FIG. 5 and the semiconductor device 1 in FIG. 1 is that the semiconductor stack 12 includes multiple semiconductor units on the substrate 10 separated by a trench 36. The multiple semiconductor units include, for example, first and second semiconductor units C1 and C2. The trench 36 penetrates through the semiconductor stack 12 and extends to the substrate 10. The trench 36 is defined by the upper surface 10a of the substrate 10 and the facing side surfaces of two adjacent semiconductor units C1 and C2. The first current blocking structure 7 is located on the first semiconductor unit C1.

In some embodiments, the semiconductor device 2 further includes a conductive structure 60. As shown in FIGS. 5 and 6A, the conductive structure 60 is formed in the trench 36 between semiconductor units C1 and C2 and on the semiconductor units C1 and C2. The two ends of the conductive structure 60 respectively connect to electrodes on the semiconductor units C1 and C2 to electrically connect C1 and C2 in series or in parallel, forming a semiconductor array. In this embodiment, one end of the conductive structure 60 connects to the first extending portion 312 of the first electrode 30 on the second semiconductor unit C2, and the other end connects to the second extending portion 212 of the second electrode 20 on the first semiconductor unit C1, forming a series connection between C1 and C2. The conductive structure 60 may include metals, such as the same metals as used for electrodes 30 and 20.

In the embodiment shown in FIG. 5, in plan view, the first electrode 30 includes the first contact portion 311 disposed on the first semiconductor unit C1 and one or more first extending portions 312 disposed on the first semiconductor unit C1 and the second semiconductor unit C2. A portion of the first extending portions 312 is formed on both sides of the first contact portion 311 and is connected thereto, while another portion extends along the long edge of the substrate 10 at the edge of the second semiconductor unit C2 and is connected to the conductive structure 60. The second electrode 20 includes the second contact portion 211 disposed on the second semiconductor unit C2 and a plurality of second extending portions 212 disposed on the first semiconductor unit C1.

In some embodiments, the semiconductor device 2 includes a third current blocking structure 9 disposed under the conductive structure 60. Specifically, as shown in FIG. 6A, the third current blocking structure 9 covers the upper surface 10a of the substrate 10 within the trench 36, as well as the side surfaces of the semiconductor units C1 and C2 that face each other across the trench 36, and further extends onto the semiconductor stack 12 of each of the semiconductor units C1 and C2. In some embodiments, as shown in FIGS. 5, 6A, and 6B, the third current blocking structure 9 includes a connecting portion 911 disposed under the conductive structure 60 and multiple third finger portions 912 respectively disposed under and corresponding to the first extending portions 312. The connecting portion 911 and the third finger portions 912 may be connected to one another. For example, as shown in FIG. 5, the connecting portion 911 is disposed along the trench 36 and may be implemented as a single continuous unit disposed under multiple conductive structures 60. Alternatively, the connecting portion 911 may include multiple discrete units respectively corresponding to multiple conductive structures 60.

As shown in FIG. 6A, the third current blocking structure 9 includes a bottom structure 90 and a reflective structure 92 disposed (e.g., stacked) on the bottom structure 90. The bottom structure 90 includes a fifth portion 901 over which the reflective structure 92 is disposed and a sixth portion 902 that is not covered by the reflective structure 92. In some embodiments, the protective structure 71 and the bottom structure 90 are formed of the same material, and the protective structure 71 and the sixth portion 902 have substantially the same thickness. In some embodiments, the sixth portion 902 and any one of the second portion 702 and the fourth portion 802 may include the same material. The sixth portion 902 and any one of the second portion 702 and the fourth portion 802 may have substantially the same thickness. In some embodiments shown in FIG. 5, in a plan view, the protective structure 71 is connected to the bottom structure 90. In other embodiments (not shown), the protective structure 71 and the bottom structure 90 may be separated. For brevity, the detailed description of the third current blocking structure 9 is omitted because it is similar to the first current blocking structure 7; reference is made to the foregoing description of the first current blocking structure 7.

In some embodiments, as shown in FIG. 6A, the insulating structure 50 covers the first electrode 30, second electrode 20, conductive layer 18, protective structure 71, semiconductor units C1 and C2, and the conductive structure 60. In one embodiment shown in FIG. 6A, the semiconductor device 2 does not include the second current blocking structure 8. In another embodiment shown in FIG. 6B, the second current blocking structure 8 is located between the first-type semiconductor structure 121 on the first semiconductor unit C1 and the second extending portion 212. As shown in FIG. 6B, the second current blocking structure 8 is separated from the third current blocking structure 9. In different embodiments, depending on the arrangement of the second electrode 20, the second current blocking structure 8 may be located between the first-type semiconductor structure 121 on the second semiconductor unit C2 and the second contact portion 211.

For elements of the semiconductor device 2 that share the same names and reference numerals as those of the semiconductor device 1 and are not specifically described herein, reference is made to the description of device 1. Such details are omitted for brevity.

FIGS. 7A-7D show cross-sectional views of the semiconductor device 1 at various manufacturing stages in accordance with some embodiments. Additional steps may be performed before, during, and/or after the stages described herein. In different embodiments, certain stages may be substituted or omitted. Although certain embodiments are described as being performed in a specific order, the steps may be carried out in another logically consistent order.

First, as shown in FIG. 7A, a semiconductor stack 12 is formed on a substrate 10, and then portions of the semiconductor stack 12 is etched to define the platform region LR and the mesa region MR. Next, current blocking films which include a bottom film 700 for forming the bottom structure and a reflective film 720 for forming the reflective structure are disposed on the semiconductor stack 12. As used herein, the term film refers to a deposited layer implemented as a single layer or as a multilayer stack. In one embodiment, the bottom film 700 and reflective film 720 may be formed by spin coating, chemical vapor deposition (CVD), physical vapor deposition (PVD), or combinations thereof in sequence. For example, the bottom film 700 may be formed by CVD and the reflective film 720 by PVD.

Next, as shown in FIG. 7B, the current blocking films is patterned in a first patterning process. In this step, the reflective structure 72 is defined by photolithography and etching. Specifically, portions of the reflective film 720, and optionally portions of the bottom film 700, are removed by etching to expose the plane 70T of the bottom film 700. The remaining reflective film forms the reflective structure 72. In some embodiments, the first patterning process uses dry etching to yield smoother etched profiles. The bottom film 700 serves as an etch stop to protect the semiconductor stack 12 from damage during dry etching.

Next, as shown in FIG. 7C, the bottom film 700 is patterned in a second patterning process. In this step, the bottom structure 70 and the protective structure 71 are simultaneously formed by photolithography and etching. Specifically, portions of the bottom film 700 are removed to expose the upper surface 12T of the semiconductor stack 12. The remaining bottom film forms the bottom structure 70 located under the reflective structure 72 and the protective structure 71 located on the side surface 12S of the semiconductor stack 12. The bottom structure 70 and reflective structure 72 together constitute the first current blocking structure 7. In some embodiments, wet etching can be applied in the second patterning process to avoid damage to the semiconductor stack 12.

In one embodiment, the bottom film 700 is not removed during the first patterning process; after the second patterning process, the thickness T1 of the first portion 701 may be equal to the thickness T2 of the second portion 702, as shown in FIG. 3A. In another embodiment, during the first patterning process, portions of the bottom film 700 are removed in addition to portions of the reflective film 720; thereafter, after the second patterning process, the thickness T1 is greater than the thickness T2, as shown in FIG. 3B. In some embodiments, forming the bottom structure 70 and the protective structure 71 in the same process step reduces process complexity and manufacturing cost. Accordingly, the protective structure 71 and the second portion 702 of the bottom structure 70 have substantially the same thickness T2.

In the present application, the photolithography process may include photoresist coating, soft bake, hard bake, mask alignment, exposure, post-exposure bake (PEB), development, rinsing, drying, or other suitable processes. The etching process may be dry etching, wet etching, or combinations thereof. Dry etching may include plasma etching (PE), reactive ion etching (RIE), and inductively coupled plasma reactive ion etching (ICP-RIE). Wet etching may use acidic or alkaline solutions.

Next, as shown in FIG. 7D, the conductive layer 18 is formed on the first current blocking structure 7 by, for example, deposition and etching. The conductive layer 18 covers the current blocking structure 7 and the upper surface 12T of the semiconductor stack 12. In some embodiments, the conductive layer 18 further extends on portions of the protective structure 71. Subsequently, an electrode material (not shown) is formed on the conductive layer 18 and then patterned to form the first electrode 30. After forming the first electrode 30, subsequent processes may be carried out as needed to form the semiconductor device 1 of FIG. 2A. Details are not repeated here.

In other embodiments, the current blocking films (including the bottom film 700 and the reflective film 720) may be formed on the first-type semiconductor structure 121 in the platform region LR. Through the foregoing first and second patterning processes, these films are patterned to form the bottom structure 80 and the reflective structure 82 of the second current blocking structure 8, as shown in FIGS. 1, 2A, and 2B. In some embodiments, the semiconductor device 1 includes both the first current blocking structure 7 and the second current blocking structure 8, which are formed in the same process.

In other embodiments of the manufacturing method for the semiconductor device 2 (not shown), after forming multiple semiconductor units of the semiconductor stack 12 on the substrate 10, the current blocking films are formed in the trench 36 and on the semiconductor units at both sides of the trench 36. Through the first and second patterning processes, the current blocking films in the trench 36 and on the adjacent semiconductor units are formed into the bottom structure 90 and reflective structure 92 of the third current blocking structure 9. In some embodiments, the semiconductor device 2 includes the current blocking structures 7, 8, and 9 which can be formed in the same process.

In summary, the present embodiments provide a semiconductor device having the current blocking structure. The current blocking structure blocks current from directly injecting into the semiconductor stack beneath the electrodes and increase lateral current spreading. The reflective structure of the current blocking structure increases reflectivity and enhances light extraction efficiency. During the patterning process for forming the current blocking structure, the bottom structure prevents damage to the underlying semiconductor stack. Additionally, the protective structure on the side surface of the semiconductor stack protects the semiconductor device and/or the semiconductor stack by blocking moisture ingress. Forming the bottom structure and the protective structure in the same process reduces process complexity and manufacturing cost.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A semiconductor device comprising:
a semiconductor stack comprising an upper surface and a side surface;
a first current blocking structure disposed on the upper surface, and comprises:
a bottom structure comprising a first portion and a second portion; and
a reflective structure disposed on the first portion without covering the second portion;
a protective structure located on the side surface and spaced apart from the first current blocking structure; and
a conductive layer covering the first current blocking structure;
wherein the protective structure and the bottom structure comprise the same material, and the protective structure and the second portion have substantially the same thickness.

2. The semiconductor device of claim 1, further comprising a first electrode disposed on the conductive layer and overlapping the first current blocking structure.

3. The semiconductor device of claim 2, wherein in a plan view, each of the bottom structure, the reflective structure, and the first electrode comprises a projection onto the upper surface, and wherein the contour of the projection of the reflective structure lies between the contours of the respective projections of the first electrode and the bottom structure.

4. The semiconductor device of claim 1, wherein the reflective structure comprises a first side surface and the second portion comprises a second side surface, and a slope of the first side surface is steeper than a slope of the second side surface.

5. The semiconductor device of claim 1, wherein a thickness of the reflective structure is greater than a thickness of the bottom structure.

6. The semiconductor device of claim 1, wherein a thickness of the first portion is greater than a thickness of the second portion.

7. The semiconductor device of claim 1, wherein the bottom structure comprises multiple layers.

8. The semiconductor device of claim 1, wherein the reflective structure comprises a distributed Bragg reflector.

9. The semiconductor device of claim 1, wherein the bottom structure and the reflective structure have different reflectivities at an emission wavelength of the semiconductor stack.

10. The semiconductor device of claim 9, wherein the reflective structure has a reflectivity of 70-100% at the emission wavelength of the semiconductor stack.

11. The semiconductor device of claim 1, wherein the conductive layer further covers the protective structure.

12. The semiconductor device of claim 1, wherein the semiconductor stack comprises a first-type semiconductor structure, an active structure, and a second-type semiconductor structure, and wherein the first current blocking structure is located on the second-type semiconductor structure.

13. The semiconductor device of claim 12, further comprising:
a second current blocking structure disposed on the first-type semiconductor structure; and
a second electrode covering the second current blocking structure and electrically connected to the first-type semiconductor structure.

14. The semiconductor device of claim 13, wherein the second current blocking structure comprises:
a second bottom structure comprising a third portion and a fourth portion; and
a second reflective structure disposed on the third portion without covering the fourth portion.

15. The semiconductor device of claim 14, wherein the fourth portion comprises a thickness substantially the same as that of the second portion.

16. The semiconductor device of claim 2, further comprising:
an insulating structure covering the first electrode, the conductive layer, and the protective structure and comprising an opening located on the first electrode; and
a first bonding pad disposed on the insulating structure and filling the opening to electrically connect to the first electrode.

17. The semiconductor device of claim 1, wherein the semiconductor stack comprises a first semiconductor unit and a second semiconductor unit separated from each other;
wherein the semiconductor device further comprises a conductive structure electrically connecting the first semiconductor unit and the second semiconductor unit.

18. The semiconductor device of claim 17, further comprising a third current blocking structure located under the conductive structure, wherein the third current blocking structure comprises:
a third bottom structure comprising a fifth portion and a sixth portion; and
a third reflective structure disposed on the fifth portion, wherein the third reflective structure does not cover the sixth portion.

19. The semiconductor device of claim 18, wherein the protective structure and the third bottom structure comprise the same material, and the protective structure and the sixth portion have substantially the same thickness.

20. The semiconductor device of claim 18, wherein the protective structure is connected to the third bottom structure.
